(19) United States
(12) Patent Application Publication
(10) Pub. No.: US 2014/0053775 A1
(43) Pub. Date: Feb. 27, 2014

(54) Chemical-Vapor-Deposition Repair Apparatus

(71) Applicants: Hefei BOE Optoelectronics Technology Co., Ltd., Hefei (CN); BOE Technology Group Co., Ltd., BEIJING (CN)

(72) Inventors: Wen Wang, Beijing (CN); Guoquan Liu, Beijing (CN); Jianmin Li, Beijing (CN); Jie Zheng, Beijing (CN); Fei Teng, Beijing (CN)

(73) Assignees: Hefei BOE Optoelectronics Technology Co., Ltd., Hefei (CN); BOE Technology Group Co., Ltd., Beijing (CN)

(21) Appl. No.: 13/973,402

(22) Filed: Aug. 22, 2013

(30) Foreign Application Priority Data
Aug. 24, 2012 (CN) 201210307094.8

(51) Int. Cl. C23C 16/52

(52) U.S. Cl. CPC C23C 16/52
USPC 118/712

(57) ABSTRACT

Embodiments of the present invention provide a CVD repair apparatus, in which an auxiliary gas is ejected from a gas-storage module, impinging upon a substrate, and bounced back to a pressure-sensitive sensor provided on a lower surface of a gas-ejection device, so that the gas pressure is detected, and based on the detected gas pressure, the distance between the substrate and the gas-ejection device is determined; when the distance between the substrate and the gas-ejection device is less than a preset lower-limit value, by increasing the auxiliary-gas amount ejected from the gas-storage module to lift up the gas-ejection device, or by preventing the gas-ejection device from moving parallel to the substrate, the substrate is avoided an inadvertent scratch during the movement of the gas-ejection device.

### FIELD OF THE INVENTION

The present invention relates to a chemical-vapor-deposition repair apparatus.

### BACKGROUND OF THE INVENTION

During preparation of a display module of a LCD display device, sometimes a malfunction spot with a metallic film rupture or a defect may appear on a Thin Film Transistor (TFT) array substrate. In this case, it will be a waste to abandon the whole display module, and therefore, a Chemical Vapor Deposition (CVD) repair apparatus can be employed to repair the display module.

When using an existing CVD repair apparatus to repair a TFT array substrate, Hexacarbonyltungsten is ejected along with an inert gas from the CVD repair apparatus, and is decomposed by laser into tungsten powder which is deposited on the TFT array substrate, to repair the rupture or defect.

During above-mentioned repair process of the TFT array substrate, when detecting a malfunction condition, the distance between the gas window and the TFT array substrate is usually less than 1 mm. At this point, when moving along x and y axes to examine the next malfunction spot, without lift-up along z axis, the gas window will scratch the TFT array substrate, which may cause a substantial damage to the TFT array substrate.

### SUMMARY

According to embodiments of the present invention, a chemical-vapor-deposition repair apparatus is provided, comprising a gas-ejection device which is used to eject a metallic compound by using inert gas so that the metallic compound is decomposed by laser into a metal and the metal is deposited on a substrate, wherein the gas-ejection device comprises: a gas-storage module, which is in fluid communication with an auxiliary-gas-supply duct, and used to eject an auxiliary gas towards the substrate through a gas outlet provided in the lower surface of the gas-ejection device; a pressure-sensitive sensor, which is provided in the lower surface of the gas-ejection device, and used to detect the gas pressure of the auxiliary gas bounced back to the lower surface of the gas-ejection device after impingement upon the substrate; and a controller, which receives a signal indicating the gas pressure detected by the pressure-sensitive sensor, to determine the distance between the substrate and the gas-ejection device based on the detected gas pressure, and to increase the auxiliary-gas-ejection amount of the gas-storage module when the distance is less than a preset lower-limit value.

Preferably, the gas-ejection device further comprises: a light-transmissive aperture, which is provided through the gas-ejection device, and used to allow the laser to pass through; and a gas-window module, which is in fluid communication with an inert-gas-supply duct, and used to eject the inert gas along with the metallic compound into the light-transmissive aperture, through a gas vent provided on the inner wall of the light-transmissive aperture.

Preferably, the gas-ejection device further comprises a lens, and the lens is provided in the light-transmissive aperture, close to the bottom of the light-transmissive aperture, and used to focus the laser entering into the light-transmissive aperture; and the gas vent is formed in such a position in the inner wall of the light-transmissive aperture that is closer to the bottom of the light-transmissive aperture than the lens.

Preferably, the controller is also used to stop movement of the gas-ejection device in a direction parallel to the substrate when the distance is less than the preset lower-limit value.

In some embodiments, the gas-storage module is stacked on the gas-window module.

Preferably, at least two through-holes are provided around the light-transmissive aperture, and the through-holes are in fluid communication with the gas-storage module and in fluid communication with the gas outlet. More preferably, the through-hole is inclined outwardly at an acute angle with respect to the lower surface of the gas-ejection device.

Preferably, the inner wall of the through-hole of the gas-storage module is provided with an electrical resistance heating wire.

Preferably, a solenoid valve is provided at the gas outlet of the gas-storage module, and the solenoid valve is connected with the controller; when the distance between the gas-ejection device and the substrate is less than the preset lower-limit value, the controller controls the solenoid valve to increase opening degree of the solenoid valve; and when the distance between the gas-ejection device and the substrate, detected by the pressure-sensitive sensor, is greater than a preset upper-limit value, the controller controls the solenoid valve to decrease opening degree of the solenoid valve.

Preferably, the inner wall of the gas-storage module is provided with an electrical resistance heating wire.

In other embodiments, the gas-window module is stacked on the gas-storage module.

Preferably, a solenoid valve is provided at the gas outlet of the gas-storage module, and the solenoid valve is connected with the controller; when the distance between the gas-ejection device and the substrate is less than the preset lower-limit value, the controller controls the solenoid valve to increase opening degree of the solenoid valve; and when the distance between the gas-ejection device and the substrate, detected by the pressure-sensitive sensor, is greater than a preset upper-limit value, the controller controls the solenoid valve to decrease opening degree of the solenoid valve.

Preferably, the inner wall of the gas-storage module is provided with an electrical resistance heating wire.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a structural schematic view of a gas-ejection device of a CVD repair apparatus in accordance with Embodiment 1 of the present invention;

FIG. 2 is a sectional view of the gas-ejection device of the CVD repair apparatus in accordance with Embodiment 1 of the present invention;

FIG. 3 is a structural schematic view of the CVD repair apparatus in accordance with Embodiment 1 of the present invention, when repairing a TFT array substrate.

FIG. 4 is a sectional view of the gas-ejection device of the CVD repair apparatus in accordance with Embodiment 1 of the present invention, with the through-holes being inclined;

FIG. 5 is a sectional view of a gas-ejection device of the CVD repair apparatus in accordance with Embodiment 2 of the present invention;

FIG. 6 is a sectional view of a gas-ejection device of a CVD repair apparatus in accordance with Embodiment 3 of the present invention, with a solenoid valve.

### DETAILED DESCRIPTION OF THE PREFERRED EMBODIMENTS

Embodiments of the present invention provide a CVD repair apparatus, in which an auxiliary gas is ejected from a gas-storage module, impinging upon a substrate, and bounced back to a pressure-sensitive sensor provided on a lower surface of a gas-ejection device, so that the gas pressure is detected, and based on the detected gas pressure, the distance between the substrate and the gas-ejection device can be determined; when the distance between the substrate and the gas-ejection device is less than a preset lower-limit value, by increasing the auxiliary-gas amount ejected from the gas-storage module to lift up the gas-ejection device, or by preventing the gas-ejection device from moving parallel to the substrate, an inadvertent scratch during the movement of the gas-ejection device by the substrate is avoided.

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

A detailed description of a CVD repair device apparatus in accordance with the embodiments of the present invention is provided below in connection with the companying drawings.

### EMBODIMENT 1

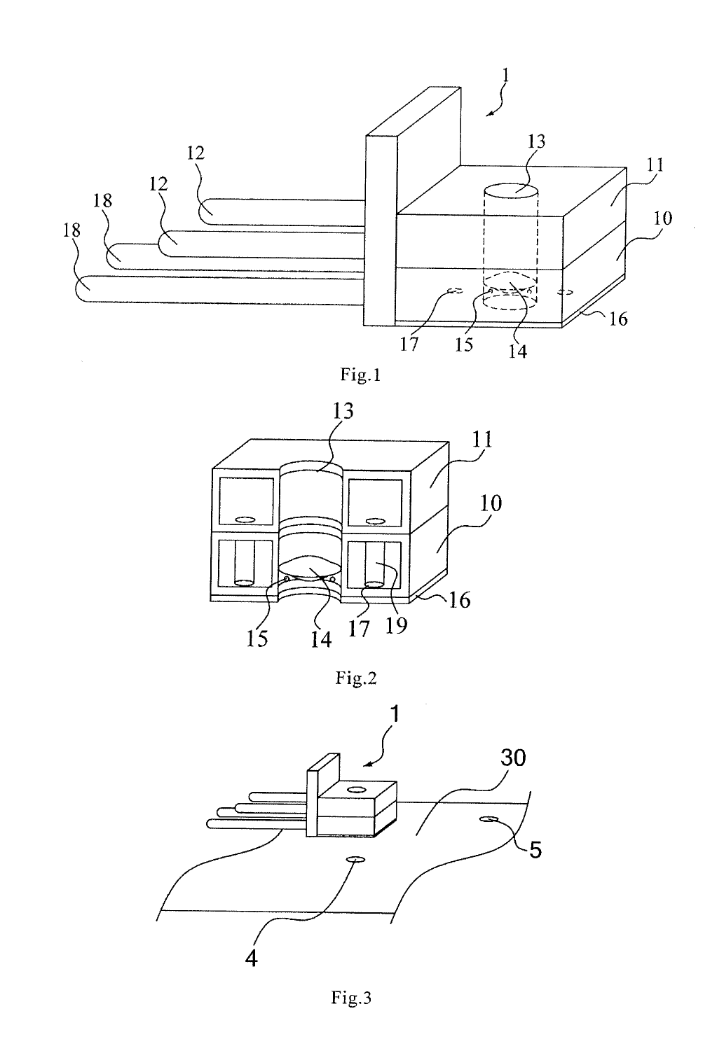

A chemical-vapor-deposition repair apparatus, as shown in FIG. 1, comprises a gas-ejection device 1 which is used to eject a metallic compound by using inert gas so that the metallic compound is decomposed by laser into a metal and the metal is deposited on a substrate.

For example, the gas-ejection device 1 can comprise:

a light-transmissive aperture 13, which is provided through the gas-ejection device 1, and used to allow the laser to pass through; and

a gas-window module 10, which is in fluid communication with an inert-gas-supply duct 18, and used to eject the inert gas along with the metallic compound into the light-transmissive aperture 13, through a gas vent 15 provided in the inner wall of the light-transmissive aperture 13.

The metallic compound can be selected as required. In the following description, herein Hexacarbonyltungsten is used as an example of the metal compound. With the action of laser, Hexacarbonyltungsten, as a metallic compound, will be formed into tungsten particles which are to be deposited on a substrate as a metal deposit.

As shown in FIG. 1, the gas-ejection device 1 can further comprise a lens 14, and the lens 14 is provided in the light-transmissive aperture 13, close to the bottom of the light-transmissive aperture 13, and used to focus the laser entering into the light-transmissive aperture.

In this case, the gas vent 15 is formed in such a position on the inner wall of the light-transmissive aperture 13 that is closer to the bottom of the light-transmissive aperture 13 than the lens 14. By focusing the laser with the use of the lens 14, the metallic compound can be more effectively decomposed into a metal deposit and deposited on the substrate.

According to this embodiment, the gas-ejection device 1 further comprises:

a gas-storage module 11, which is in fluid communication with an auxiliary-gas-supply duct 12, and used to eject an auxiliary gas towards the substrate, wherein, the gas outlet 17 of the gas-storage module 11 is provided in the lower surface of the gas-ejection device 1;

a pressure-sensitive sensor 16, which is provided in the lower surface of the gas-ejection device 1, and used to detect the gas pressure of the auxiliary gas bounced back to the lower surface of the gas-ejection device 1 after impingement upon the substrate; and

a controller (not shown), which is connected with the pressure-sensitive sensor 16, and used to receive a signal indicating the gas pressure detected by the pressure-sensitive sensor, to determine the distance between the substrate and the gas-ejection device based on the gas pressure, and to increase the auxiliary-gas-ejection amount of the gas-storage module 11 when the distance detected by pressure-sensitive module 16 is less than a preset lower-limit value.

In the CVD repair apparatus, the inert gas delivered in the inert-gas-supply duct 18 can be argon, nitrogen and/or the like; and in order to save cost, the auxiliary gas delivered in the auxiliary-gas-supply duct 12 can be nitrogen or dried air.

The gas-window module 10 and the gas-storage module 11 can have a chamber for allowing the inert gas and the auxiliary gas to pass through, respectively; the inert gas, carrying Hexacarbonyltungsten, enters into the chamber of the gas-window module 10 through the inert-gas-supply duct 18, and is ejected from the gas vent 15 in the inner wall of the light-transmissive aperture 13; and the auxiliary gas enters into the chamber of the gas-storage module 11 through the auxiliary-gas-supply duct 12 and is ejected from the gas outlet 17.

The controller of the CVD repair apparatus, can also be used to control the gas-ejection device 1 to move in a direction parallel to the substrate, to reach a corresponding malfunction spot and repair it.

In an implementation of the CVD repair apparatus in accordance with this embodiment, the gas-storage module 11 is stacked on the gas-window module 10, and the substrate is a TFT array substrate 30.

Further, as shown in FIG. 2, at least two through-holes 19 are provided around the light-transmissive aperture 13, and the through-holes 19 are in fluid communication with the gas-storage module 11 and with the gas outlet 17 of the gas-storage module 11. The number of the through-holes 19 can be set as required.

When repairing the malfunction spot 4 on the TFT array substrate 30, as shown in FIG. 3, the gas-ejection device 1 is controlled to move to the position of the detected malfunction spot 4. By ejecting an inert gas, for example argon, into the gas-window module 10 through the inert-gas-supply duct 18, Hexacarbonyltungsten stored in the tungsten storage-can (not shown) is blown into the gas-window module 10. Hexacarbonyltungsten entering the gas-window module 10, then enters the light-transmissive aperture 13 through the gas vent 15 in the inner wall of the light-transmissive aperture 13 located below the lens 14, such that the Hexacarbonyltungsten in the light-transmissive aperture 13 is located below the lens 14.

At this point, with a laser machine (not shown) of the CVD repair apparatus, a laser beam reaches the lens 14 after beam expanding, reflection, interference filtering etc. The lens 14 focuses the laser beam, to decompose the Hexacarbonyltungsten, and thus the obtained tungsten metal is deposited on the malfunction spot 4 of the TFT array substrate 30, thereby repairing the rupture or defect of the malfunction spot 4.

After repairing the malfunction spot 4, the CVD repair apparatus will move the gas-ejection device 1 to a next malfunction spot 5 to be repaired. At this point, the auxiliary gas is injected into the gas-storage module 11 through the auxiliary-gas-supply duct 12, and then ejected from the gas outlet 17 and the through-holes 19 around the light-transmissive aperture 13. The ejected auxiliary gas reaches the surface of the TFT array substrate 30, and then is bounced back to the pressure-sensitive sensor 18 in the lower surface of the gas-ejection device 1. The gas pressure is then detected by the pressure-sensitive sensor 16. The controller can determine the distance between the gas-ejection device 1 and the TFT array substrate 30, based on the detected gas pressure. When the distance is less than a preset lower-limit value, it indicates that the distance between the TFT array substrate 30 and the gas-ejection device 1 is too small, which means that the TFT array substrate is likely to be scratched during movement of the gas-ejection device 1. When the CVD repair apparatus is informed that the distance between the gas-ejection device 1 and the TFT array substrate 30 is too small, the auxiliary-gas-ejection amount blown out from the auxiliary-gas-supply duct 12 can be increased by the controller, thus increasing the auxiliary-gas-ejection amount ejected from the gas outlet 17 of the gas-storage module 11, thereby assisting increasing the distance between the gas-ejection device 1 and the TFT array substrate 30 in a direction perpendicular to the substrate and preventing the gas-ejection device 1 from scratching the TFT array substrate 30 due to the close distance therebetween.

In a preferred embodiment, the controller can also be used to stop the gas-ejection device 1 from moving laterally (in a direction parallel to the substrate), when the distance detected by the pressure-sensitive sensor 16 is less than the preset lower-limit value. That is, when the detected distance between the gas-ejection device 1 and the TFT array substrate 30 is less than the preset lower-limit value, the gas-ejection device 1 is prevented from moving laterally, until the gas-ejection device 1 is lifted up in the direction perpendicular to the substrate, thus further preventing the gas-ejection device 1 from scratching the TFT array substrate 30.

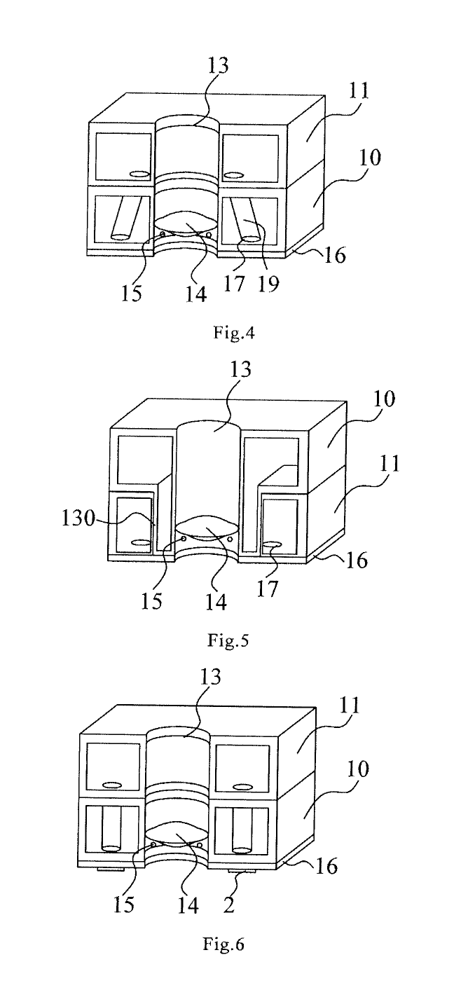

In a preferred embodiment, as shown in FIG. 4, the through-holes 19 are inclined outwardly at an acute angle with respect to the lower surface of the gas-ejection device 1. As the through-holes 19 are inclined outwardly, the auxiliary gas ejected through such through-holes from center towards outside, can blow away the dusts on the surface of the TFT array substrate 30, and thus makes the substrate cleaner after repairing.

In the CVD repair apparatus, an electrical resistance heating wire can be provided below the platform—which the TFT array substrate 30 is disposed thereon—for heating the TFT array substrate 30, so as to keep the temperature of the TFT array substrate 30 to be above the crystallization point of Tungsten, thereby preventing Tungsten from crystallizing when depositing on the TFT array substrate 30. However, when the ambient temperature is too low, the temperature of the TFT array substrate 30 can be decreased along with the ambient temperature. In this situation, the tungsten particle can be crystallized when depositing, which will hinder the repair from being proceeded.

To solve the crystallizing issue of Tungsten, according to the embodiments of the present invention, an electrical resistance heating wire is further provided in the inner wall of the through-hole 19 of the gas-storage module 11.

By providing the electrical resistance heating wire in the inner wall, the auxiliary gas is heated when ejected. The ambient temperature is thus increased with the heated ejected auxiliary gas, thereby increasing the temperature within the CVD repair apparatus, preventing the Tungsten particles from crystallizing, and improving the success rate of the repair.

The electrical resistance heating wire can also be provided in the inner wall of the gas-storage module 11. In this way, likewise, the auxiliary gas can also be heated to increase the temperature within the CVD repair apparatus, thereby preventing the Tungsten particles from crystallizing and improving the success rate of repairs.

### EMBODIMENT 2

Unlike the embodiment 1, in the CVD repair in accordance with this embodiment, as shown in FIG. 5, the gas-window module 10 is stacked on the gas-storage module 11. In this case, the gas-window module 10 comprises an extension portion 130 which is in a hollow cylinder shape and extends downwardly, and the extension portion 130 surrounds the light-transmissive aperture 13, passes through the gas-storage module 11, and reaches a position at or near the lower surface of the gas-ejection device 1. The lens 14 is provided in a part of the light-transmissive aperture 13 corresponding to the extension portion 130, and the gas vent 15 which is used for ejecting the inert gas carrying Hexacarbonyltungsten is provided below the lens 14.

In this case, the gas outlet 17 of the gas-storage module 11 is provided directly on the body of the gas-storage module 11, to eject the auxiliary gas.

The control procedure for preventing scratching the TFT array substrate and the method of heating the auxiliary gas for increasing the temperature within the CVD repair apparatus are the same as in Embodiment 1, which will not be further described here.

In the CVD repair apparatus, an electrical resistance heating wire can be provided below the platform—which the TFT array substrate 30 is disposed thereon—for heating the TFT array substrate 30, so as to keep the temperature of the TFT array substrate 30 to be above the crystallization point of Tungsten, thereby preventing Tungsten from crystallizing when depositing on the TFT array substrate 30. However, when the ambient temperature is too low, the temperature of the TFT array substrate 30 can be decreased along with the ambient temperature. In this situation, the tungsten particle can be crystallized when depositing, which will hinder the repair from being proceeded.

To solve the crystallizing issue of Tungsten, an electrical resistance heating wire is further provided in the inner wall of the through-hole 19 of the gas-storage module 11.

By providing the electrical resistance heating wire in the inner wall, the auxiliary gas is heated when ejected. The ambient temperature is thus increased with the heated ejected auxiliary gas, thereby increasing the temperature within the CVD repair apparatus, preventing the Tungsten particles from crystallizing, and improving the success rate of the repair.

### EMBODIMENT 3

Furthermore, in the CVD repair apparatus in accordance with Embodiment 1 and Embodiment 2, a solenoid valve 2 is provided at the gas outlet 17 of the gas-storage module 11, and the solenoid valve 2 is connected with the controller, as shown in FIG. 6.

When the distance between the gas-ejection device 1 and the substrate 3 is less than a preset lower-limit value, the controller controls the solenoid valve 2 to fully open;

When the distance between the gas-ejection device 1 and the substrate 3 is greater than a preset upper-limit value, the controller controls the solenoid valve 2 to decrease opening degree.

In the illustrated example, the substrate is a TFT array substrate 30 as described in Embodiment 1 and 2. During repairing, when the distance between the gas-ejection device 1 and the substrate is greater than a preset upper-limit value, the CVD repair apparatus controls the solenoid valve 22 to decrease its opening degree, thereby shortening the distance between the gas-ejection device 1 and the substrate, so as to ensure that the metal, such as the Tungsten obtained by decomposition, is effectively deposited on the substrate.

When the distance between the gas-ejection device 1 and the TFT array substrate 30 is less than a preset lower-limit value, the CVD repair apparatus controls the solenoid valve to increase its opening degree, thereby increasing the auxiliary-gas-ejection amount. In this case, as the auxiliary-gas-ejection amount is increased, the gas-ejection device 1 is lifted up, thereby increasing the distance between the gas-ejection device 1 and the TFT array substrate 30, thus preventing the gas ejection mean 1 from scratching the TFT array substrate 30 due to the too close distance therebetween during moving, thereby improving the success rate of the repairing of the TFT array substrate 30 with the CVD repair apparatus.

In addition, in the present invention, the metallic compound ejected from the gas-window module 10 is not limited to Hexacarbonyltungsten, and can be any other suitable metallic compound; the repairing target is also not limited to the TFT array substrate 30.

While the above is merely specific implementation of the present invention, the scope of the present invention is not limited thereto. Within the technical scope disclosed by the invention, modifications or alterations that can be easily devised by those skilled who are familiar with the art, should all be included within the scope of the present invention. Therefore, the scope of protection of the invention should be defined by the scope of protection of the claims.

What is claimed is:

1. A chemical-vapor-deposition repair apparatus, comprising a gas-ejection device which is used to eject a metallic compound by using inert gas so that the metallic compound is decomposed into a metal by laser and the metal is deposited on a substrate, wherein, the gas-ejection device comprises:
a gas-storage module, which is in fluid communication with an auxiliary-gas-supply duct, and used to eject an auxiliary gas towards the substrate through a gas outlet provided in the lower surface of the gas-ejection device;
a pressure-sensitive sensor, which is provided in the lower surface of the gas-ejection device, and used to detect the gas pressure of the auxiliary gas bounced back to the lower surface of the gas-ejection device after impingement upon the substrate; and
a controller, which receives a signal indicating the gas pressure detected by the pressure-sensitive sensor, to determine the distance between the substrate and the gas-ejection device based on the detected gas pressure, and to increase the auxiliary-gas-ejection amount of the gas-storage module when the distance is less than a preset lower-limit value.

2. The chemical-vapor-deposition repair apparatus according to claim 1, wherein, the gas-ejection device further comprises:
a light-transmissive aperture, which is provided through the gas-ejection device, and used to allow the laser to pass through; and
a gas-window module, which is in fluid communication with an inert-gas-supply duct, and used to eject the inert gas along with the metallic compound into the light-transmissive aperture, through a gas vent provided in an inner wall of the light-transmissive aperture.

3. The chemical-vapor-deposition repair apparatus according to claim 2, wherein, the gas-ejection device further comprises a lens, and the lens is provided in the light-transmissive aperture, close to the bottom of the light-transmissive aperture, and used to focus the laser entering into the light-transmissive aperture; and
the gas vent is formed in such a position in the inner wall of the light-transmissive aperture that is closer to the bottom of the light-transmissive aperture than the lens.

4. The chemical-vapor-deposition repair apparatus according to claim 1, wherein, the controller is also used to stop movement of the gas-ejection device in a direction parallel to the substrate when the distance is less than the preset lower-limit value.

5. The chemical-vapor-deposition repair apparatus according to claim 2, wherein, the gas-storage module is stacked on the gas-window module.

6. The chemical-vapor-deposition repair apparatus according to claim 5, wherein, at least two through-holes are provided around the light-transmissive aperture, and the through-holes are in fluid communication with the gas-storage module and in fluid communication with the gas outlet.

7. The chemical-vapor-deposition repair apparatus according to claim 6, wherein, the through-hole is inclined outwardly at an acute angle with respect to the lower surface of the gas-ejection device.

8. The chemical-vapor-deposition repair apparatus according to claim 7, wherein, the inner wall of the through-hole of the gas-storage module is provided with an electrical resistance heating wire.

9. The chemical-vapor-deposition repair apparatus according to claim 8, wherein, a solenoid valve is provided at the gas outlet of the gas-storage module, and the solenoid valve is connected with the controller;
when the distance between the gas-ejection device and the substrate is less than the preset lower-limit value, the controller controls the solenoid valve to increase opening degree of the solenoid valve; and
when the distance between the gas-ejection device and the substrate, detected by the pressure-sensitive sensor, is greater than a preset upper-limit value, the controller controls the solenoid valve to decrease opening degree of the solenoid valve.

10. The chemical-vapor-deposition repair apparatus according to claim 9, wherein, the inner wall of the gas-storage module is provided with an electrical resistance heating wire.

11. The chemical-vapor-deposition repair apparatus according to claim 2, wherein, the gas-window module is stacked on the gas-storage module.

12. The chemical-vapor-deposition repair apparatus according to claim 11, wherein, a solenoid valve is provided at the gas outlet of the gas-storage module, and the solenoid valve is connected with the controller;
when the distance between the gas-ejection device and the substrate is less than the preset lower-limit value, the controller controls the solenoid valve to increase opening degree of the solenoid valve; and
when the distance between the gas-ejection device and the substrate, detected by the pressure-sensitive sensor, is greater than a preset upper-limit value, the controller controls the solenoid valve to decrease opening degree of the solenoid valve.

13. The chemical-vapor-deposition repair apparatus according to claim 12, wherein, the inner wall of the gas-storage module is provided with an electrical resistance heating wire.
